(19) United States
(12) Patent Application Publication
(10) Pub. No.: US 2026/0180837 A1
(43) Pub. Date: Jun. 25, 2026

(54) CONTINUOUS TIME LINEAR EQUALIZATION CIRCUITS

(71) Applicant: Intel Corporation, Santa Clara, CA (US)

(72) Inventors: Susnata MONDAL, Hillsboro, OR (US); Mozhgan MANSURI, Portland, OR (US)

(21) Appl. No.: 18/987,358

(22) Filed: Dec. 19, 2024

(51) Int. Cl. H04L 27/01; H03H 7/06

(52) U.S. Cl. CPC H04L 27/01; H03H 7/06

(57) ABSTRACT

In some embodiments, CTLE circuits are provided with shunt RL components to facilitate substantially consistent output transmitter resistance over an operational frequency spectrum.

### TECHNICAL FIELD

Embodiments of the invention relate to the field of semiconductor circuits; and more specifically, to the field of interconnect equalization circuits.

### BRIEF DESCRIPTION OF THE DRAWINGS

The disclosure may best be understood by referring to the following description and accompanying drawings that are used to illustrate embodiments of the invention. In the drawings:

FIG. 1A is a diagram showing a conventional architecture for a wireline transmission path.

FIG. 1B is a diagram showing a conventional passive continuous time linear equalization (CTLE) circuit.

FIG. 2A is a diagram showing a transmission path circuit comprising a transmitter equalization circuit in accordance with some embodiments.

FIG. 2B is a diagram with graphs contrasting equalization responses for a conventional CTLE and the CTLE of FIG. 2A.

FIG. 2C is a diagram with graphs illustrating TX output impedance variations for a conventional CTLE and for the CTLE of FIG. 2A.

FIG. 3 is a diagram showing a transmission path circuit in accordance with some additional embodiments.

FIG. 4A is a diagram showing a transmitter circuit with a P/N Tx driver and an equalization circuit in accordance with some embodiments.

FIG. 4B is a diagram showing output reflection coefficient values for P/N driver transmitter circuits with and without a CTLE as disclosed herein in accordance with some embodiments.

FIG. 5 shows a portion of a system with interconnect interface circuits in accordance with some embodiments.

FIG. 6 illustrates an example computing system in accordance with some embodiments.

FIG. 7 illustrates a block diagram of an example processor and/or SoC in accordance with some embodiments.

FIG. 8 is a block diagram illustrating a computing system 800 configured to implement one or more aspects of the examples described herein.

### DETAILED DESCRIPTION

As data rates continue to increase, higher electrical channel losses demand more effective and energy efficient equalization schemes in wireline interconnects, such as in Universal Chiplet Interconnect Express (UCIe) for die-to-die IO, as well as for off-package IO, e.g., through the bottom side or the top side of a package, Peripheral Component Interconnect Express (PCIe), etc. By maintaining CTLE (continuous time linear equalization) output matching across frequencies, some embodiments disclosed herein enable passive-CTLE-based equalization with source-matched transmission schemes, achieving better energy efficiency, eye margins, and TX supply noise suppression, as compared with conventional approaches such as FFE (feed forward equalization) based solutions.

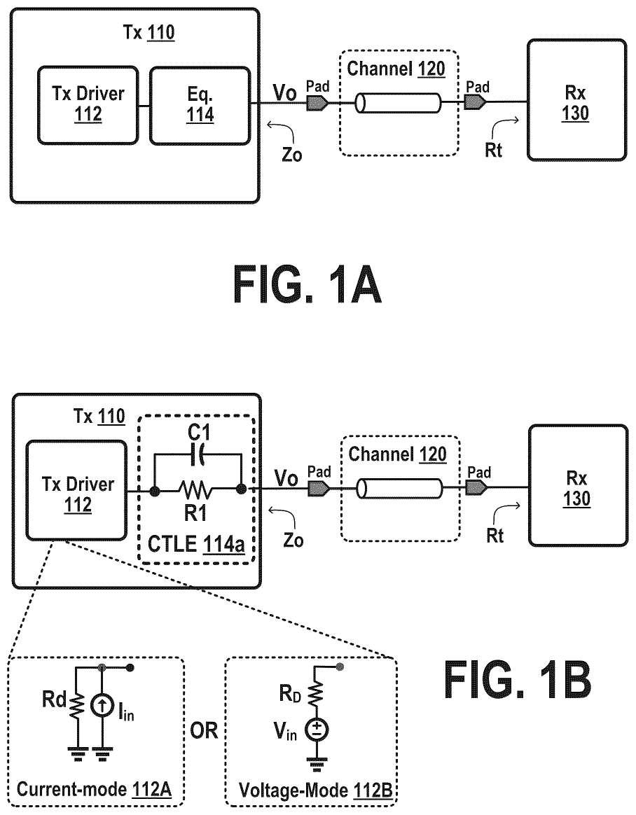

FIG. 1A is a diagram showing a conventional architecture for a wireline transmission path. In general, a transmitter (Tx) 110, comprising a driver 112 and equalization 114, transmits a signal over a channel 120 to a receiver (Rx) 130. The receiver includes termination resistance (Rt) to minimize reflection losses. However, as a result of non-uniform frequency-dependent channel losses, aggressive data-rate scaling with link protocols such as with UCIe (Universal Chiplet Interconnect Express), PCIe (Peripheral Component Interconnect Express), and various other off-die or off-package chip-to-chip (C2C) implementations demand more effective and energy-efficient equalization schemes.

FIG. 1B is a diagram showing a conventional passive continuous time linear equalization (CTLE) circuit. With this example, a conventional CTLE 114a is used for equalization circuit 114. Also illustrated in this example are both current mode 112a and voltage mode 112b driver options, either of which may be used in a transmitter, depending on particular design considerations.

The depicted equalization circuit 114a comprises a high-pass filter formed from a resistor (R1) in parallel with a capacitor (C1). Using a single zero in the transmission pathway, this filter serves to filter lower frequency components more than higher frequency components in order to compensate for channel losses, which tend to be greater for higher frequencies. Unfortunately, this CTLE solution suffers from high output impedance variations across frequency that degrades output matching and increases reflection in the channel. For this circuit with the voltage mode driver as the Tx driver (source impedance Rd), the impedance peaking ratio (Zhi/Zlo) is: Rd/(R1+Rd), and the peaking gain ratio (Ahi/Alo) is: 1+R1/(Rt+Rd), where Zhi and Ahi are the Tx output impedance (Zo) and overall gain for signal components at frequencies approaching infinity (i.e., an asymptote of frequencies well above the transmission-zero of the filter), while Zlo and Alo are the TX output impedance and overall gain at frequencies approaching zero (i.e., an asymptote of frequencies well below the transmission-zero of the filter). Thus, it can be seen that in order to have uniform output impedance across operable frequency ranges, e.g., 0 to 64 GHz. or higher, filter resistance (R1) would have to be infinitesimally small, which results in a peaking gain approaching unity, i.e., no gain equalization from the CTLE. In other words, when realizing any desirable peaking gain, output impedance cannot be uniformly maintained across frequency.

Other conventional equalization circuits can function better, but they have their own drawbacks such as excessive power consumption. For example, TX feed-forward equalizations (FFE) can consume excessive power in driver output and multi-tap data generation stages, as well as for FFE tap strength tuning across data rates. Moreover, FFE equalizations typically suppress signal content beyond the Nyquist frequency, which limits eye margin. Fractional-unit-interval FFE designs can avoid signal suppression beyond Nyquist frequencies, but incur even more costs and complexities from tap delay tuning and also generate additional associated power consumption overhead.

Accordingly, in order to address these challenges, in some embodiments, a passive CTLE with improved output-impedance-invariance is disclosed. In some embodiments, provided is a passive TX CTLE architecture network comprising an RL leg in shunt with a series RC filter to achieve higher peaking gain from two low-frequency zeroes in the gain response with a reasonably constant output impedance from a low-frequency pole-zero pair that can compensate each other. In some embodiments, the CTLE circuit can suppress the output impedance variation by two orders of magnitude compared to conventional CTLE circuits and can outperform FFE solutions in terms of energy efficiency, eye margins, and noise transfer from the TX supply to a voltage-mode TX output. Moreover, CTLE embodiments can help linearize an inverter-based high-swing voltage-mode driver without an explicit linearization resistor, improving eye height compared to a low-swing driver without significant additional power overhead from driver or preceding stages.

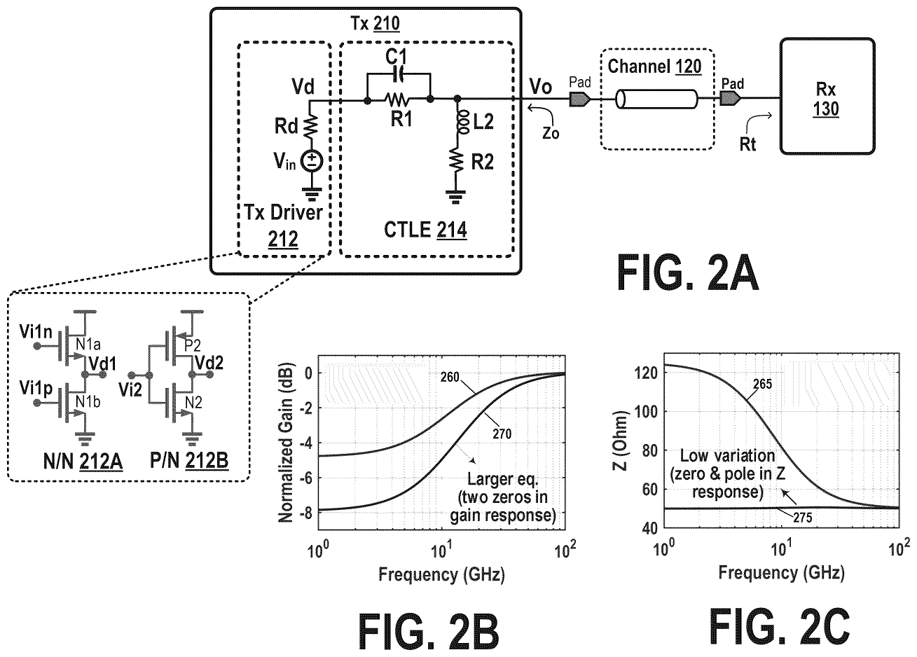

FIG. 2A is a diagram showing a transmission path circuit comprising a transmitter equalization circuit in accordance with some embodiments. FIG. 2B is a diagram with graphs contrasting equalization responses for a conventional CTLE and the CTLE of FIG. 2A. FIG. 2C is a diagram with graphs illustrating TX output impedance variation for a conventional CTLE and for the CTLE of FIG. 2A.

With the depicted circuit example of FIG. 2A, a transmitter 210 includes a Tx driver 212 and a passive CTLE (referred to simply as CTLE going forward) 214, coupled together as shown. The CTLE includes high pass filter components, R1, C1, as with the conventional circuit, but it also includes a shunt inductor L1 and resistor R2, coupled in series between the Tx output node (Vo) and a low supply reference (e.g., ground). It can be shown that the shunt R2/L1 branch in the CTLE adds an additional zero at the frequency (R2/L1) both in the gain response and in the output impedance response. Therefore, embodiments of this disclosed CTLE can have higher peaking gain with two low-frequency zeroes in the gain response with a reasonably constant output impedance from a low-frequency pole-zero pair that can be configured to roughly compensate one another. In the following section, gain and output impedance peak responses will be derived based on operational spectrum simplifications using zero frequency for the lower end of the frequency spectrum and infinite (∞) frequency for the upper end of the spectrum.

With the depicted circuit, the output impedance (Zo) approaching infinite frequency (Zhi) is: Rd, and the output impedance at zero frequency (Zlo) is: R2//(R1+Rd). (Note that “//” refers to “in parallel with.”) Thus, Zhi/Zlo =(RdR2+RdRd+RdR1)/(RdR2+R1R2). When solving for R2 such that Zhi=Zlo=Rd, R2=Rd+Rd×Rd/R1, resulting in Zhi/Zlo=1 and Ahi/Alo=1+(R1/Rd). Thus, it can be seen that with this circuit, output resistance (Zo) remains constant and the peaking gain (Ahi/Alo) can be tuned by choosing R1 to arrive at a desired peaking value. (Note that with this simplified analysis, output impedance and output resistance are used interchangeably as at these two asymptotic frequencies of zero and infinite the output impedance doesn't have reactive components.)

A design example will now be presented. Assume that channel losses are 6 dB across a utilized broadband spectrum. So, we define R1, R2 to achieve a peaking gain (Ahi/Alo)=6 dB to compensate for the channel losses. Since peaking gain, in decibels, for this circuit is: 20(Log(1+R1/Rd)), then, with a desired peak gain ratio of 6 dB, we take the inverse Log of 6/20 and arrive at (1+R1/Rd) is equal to 1.999 (rounded to 2). Therefore, to achieve a 6 dB peaking gain, we would set R1 equal to Rd.

The output impedance (Zo) is generally predefined for a given wireline standard. For example, with a UCIe implementation, Zo, which is also equal to Rd here, might be equal to 30 Ohms. If this is the case, we then set R1=30 Ohms (R1=Rd). Now, with R1=30 Ohms, we can determine R2 from: R2=Rd+Rd×Rd/R1, or, R1=30+(30)²/30 =60 Ohms. So, with this circuit example, we achieve a desirable gain response and a uniform output driver impedance (resistance) (Zo) over the entire frequency range with R1=30 Ohms and R2=60 Ohms.

As illustrated in FIG. 2B, it can be seen that with the disclosed circuit, the gain peaking, i.e., the gain at high frequency (Ahi) versus low frequency (Alo), is higher, which in many scenarios, will be an improvement over conventional circuits. Moreover, as shown in FIG. 2C, the output impedance of the proposed passive CTLE remains the same at high frequency (Zhi) versus low frequency (Zlo).

Thus, with disclosed implementations that incorporate the two low-frequency zeroes in the gain response, passive TX CTLE architectures are provided that can achieve higher peaking gain than conventional CTLE equalizations. Moreover, embodiments can also achieve a reasonably constant output impedance with pole-zero pair cancellation in the output impedance response. In addition, CTLE embodiments disclosed herein may achieve better eye margins and driver energy efficiency, e.g., as compared with FFE implementations. They also can suppress unmodulated TX supply noise and can avoid additional power overhead as may be incurred with FFE solutions.

With the depicted transmitter circuit 210, two different voltage mode drivers, 212A, 212B, are shown. Either may be used to implement a Tx driver 212. The first driver, 212A, is a so-called N/N driver with stacked N-type MOS transistors N1a, N1b. The devices have separate inputs (Vi1n, Vi1p) so that they may be switched on in a complementary manner. A benefit of using two N-type transistors in this way is that, as compared with the P/N counterpart, within switching cycles, both transistors spend more time either off or in triode (linear) operational mode regions. This serves to maintain the driver output resistance (Rd) at a reasonably lower level. However, since they are both N-type devices, the driver, as compared with a P/N driver, will have a lower output swing capability.

Alternatively, the P/N driver, 212B, is formed from stacked together P and N type transistors (P2, N2) as shown. With this driver, switching is simpler since only one input (Vi2) is required. In addition, the driver will likely have better output swing capability than the N/N counterpart. However, as compared with the N/N driver, the P and N devices can spend more switching time in saturation mode regions, which causes the driver's output resistance to be larger. Thus, depending on particular design considerations, one of the two driver options may be better suited for a given application.

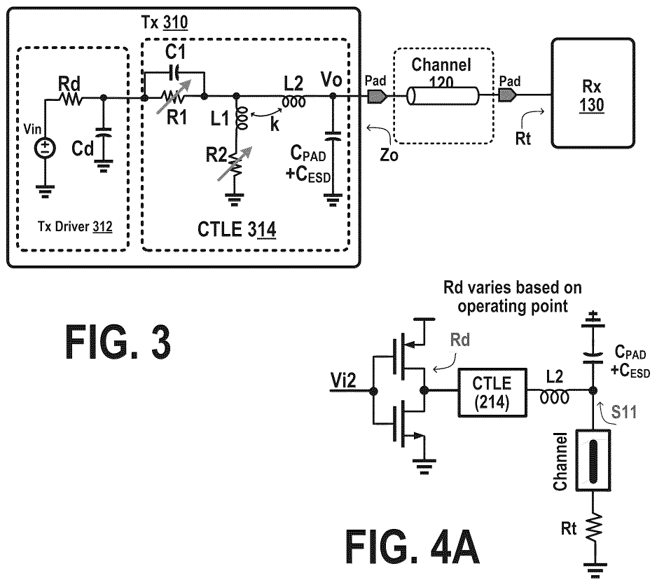

FIG. 3 is a diagram showing a transmission path circuit in accordance with some additional embodiments. This implementation is similar to the circuit of FIG. 2A, but it also includes an output peaking inductor (L2) and illustrates the parasitic capacitances that are present in many implementations. The peaking inductor, L2, among other things, resonantly compensates for the parasitic capacitances including parasitic driver capacitance (Cd) and capacitances from the output pad and ESD protection structure.

Also included in this example are variable resistors used for R1 and R2. It is challenging with typical high volume manufacturing (HVM) techniques to implement variable inductors and capacitors with low parasitics overhead. Accordingly, in some embodiments, variable resistors may be used for R1 and/or R2, e.g., with selectively engageable parallel resistive legs, to tune the resistances of R1 and R2 in accordance with the equations discussed above and to provide flexibility in setting pole/zero points instead of relying solely on resistor, capacitor and inductor device parameters to be made within tight, deterministic tolerances. Moreover, flexibility in CTLE design parameters is beneficial as the channel loss, which the CTLE compensates, can also change based on channel electrical properties and length. For context, in some embodiments, with the circuits of FIG. 2A or 3, while any suitable combination of capacitor and inductor values may be used, in one example, capacitor C1 has a value of 700 fF, L1 has a value of 150 pH, and L2 has a value of 600 pH.

In some implementations, such as with UCIe links, a very small amount of space is allotted for each transmission pathway circuit. usually, this can limit the amount and sizes of capacitors and/or inductors that may be used for each equalization circuit. However, in some embodiments, both the shunt inductor (L1) and peaking inductor (L2) may be included by disposing them in separate metal layers (e.g., metal layers 1, 2) that substantially overlap one another. This may be done with a tolerable amount of constructive inductive coupling (e.g., factor up to 0.3) and fit within the footprint space provided to a given Tx circuit.

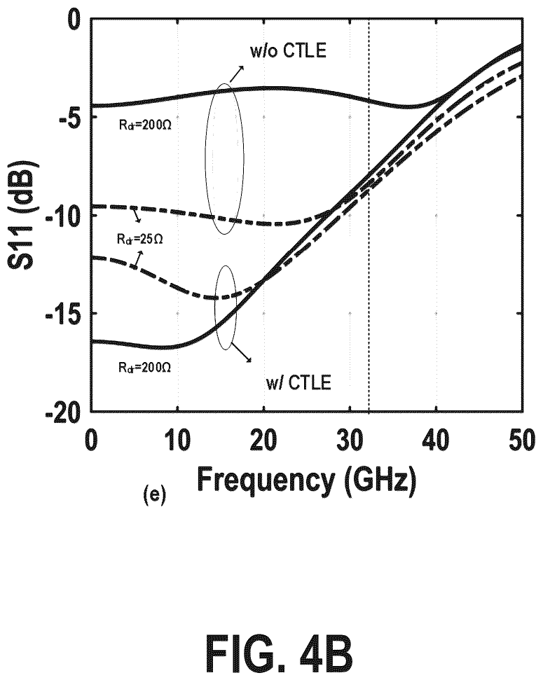

FIG. 4A is a diagram showing a transmitter circuit with a P/N Tx driver and an equalization circuit in accordance with some embodiments. For example, a P/N driver such as 212B and a CTLE 214 from FIG. 2A may be used. As mentioned above, P/N drivers can have less favorable driver output resistance characteristics, as compared with their N/N counterparts, but they may be desired in certain environments where a wider output swing capability is needed. They can improve TX swing and overall eye height. However, P/N drivers tend to have a non-linear output impedance that has traditionally required an explicit linearization resistor at the cost of larger driver and pre-driver sizes with higher power consumption. To this end, the disclosed CTLE (e.g., 214) can help linearize the TX output impedance of a voltage mode P/N driver without having to excessively scale up the driver and pre-driver sizes. The utilized CTLE network helps reduce TX output impedance variation even with higher impedance variation of the driver. By linearizing driver output impedance, higher swing P/N drivers can be used without the need for explicit linearizing resistances, reducing required driver sizes and in turn, reducing required sizes needed for preceding stages and thereby improving energy efficiency. This is indicated with the signal diagram of FIG. 4B, which is a diagram showing output reflection coefficient with and without a CTLE network as disclosed herein for driver impedances of 25 Ω and 200 Ω. As shown for the CTLE settings to equalize the channel response, output S11 (reflectivity factor) remains under −9 dB (e.g., minimum reflection) up to Nyquist frequency with the CTLE despite a significant driver output resistance variation from 25 Ω to-200 Ω. Therefore, CTLE embodiments disclosed herein can facilitate the use of P/N drivers and improve eye height without the need for an added linearization resistance.

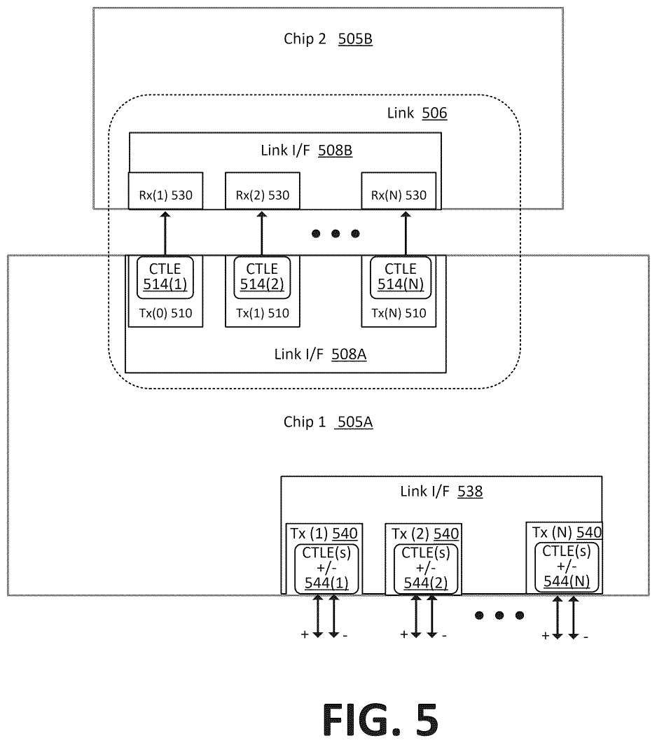

FIG. 5 shows a portion of a system with interconnect interface circuits in accordance with some embodiments. The system includes a first chip (Chip 1, 505A) and a second chip (Chip 2, 505B), coupled together through a chip-to-chip (C2C) link (or interconnect) 506. For example, link 506 may be implemented with a 32/64/128 Gb/s UCIe interconnect.

The depicted link comprises a first link interface (I/F) 508A, which is part of the first chip 505A, coupled through a plurality of channel pathways (indicated with arrows) to a corresponding second link I/F 508B, which is part of the second chip 505B. (Note that for simplicity and ease of understanding, while the link 506 may be bi-directional, only part of it is shown for transmissions from the first to the second chip.)

The first link I/F 508A includes a plurality of transmitter circuits 510 (Tx(1)-Tx(N)) configured to be coupled with corresponding receivers 530, which are part of the second link I/F 508B, through channel paths. Each of the transmitters 510 include a transmitter driver circuit (not shown) coupled with an associated CTLE equalization circuit 514 in accordance with any of the embodiments described herein. The Tx driver circuits, for example, may be implemented with voltage or current mode drivers and may use N/N and/or P/N driver configurations. Likewise, the CTLE circuits 514 may include series shunt resistor/inductors coupled to a ground (or low supply) reference and may or may not include a second inductor (peaking inductor) coupled in series to an output node to an associated channel path.

The first chip (505A) also includes an additional link interface 538 such as an off-package link interface (e.g., PCIe) to couple with a corresponding link interface counterpart from another chip, or chip package. Link I/F 538 includes differential transmitter circuits 540 (Tx1-TxN) that each include a pair of complementary Tx driver circuits (not shown) for differential wireline communications. Each transmitter 540 also includes a pair of CTLE equalization circuits 544, as disclosed herein, to perform transmitter equalization for associated differential pathway channels. These link interface examples may be employed in any of the system examples described in the following sections.

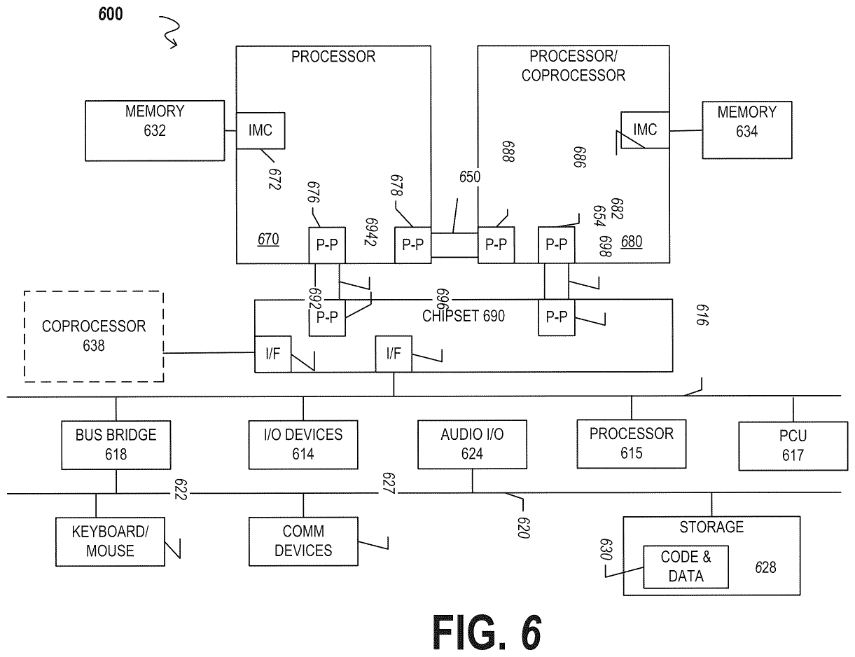

FIG. 6 illustrates an example computing system in accordance with some embodiments. Multiprocessor system 600 is an interfaced system and includes a plurality of processors including a first processor 670 and a second processor 680 coupled via an interface 650 such as a point-to-point (P-P) interconnect, a fabric, and/or bus. In some examples, the first processor 670 and the second processor 680 are homogeneous. In some examples, first processor 670 and the second processor 680 are heterogenous. Though the example system 600 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 670 and 680 are shown including integrated memory controller (IMC) circuitry 672 and 682, respectively. Processor 670 also includes interface circuits 676 and 678, along with core sets. Similarly, second processor 680 includes interface circuits 686 and 688, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 670, 680 may exchange information via the interface 650 using interface circuits 678, 688. IMCs 672 and 682 couple the processors 670, 680 to respective memories, namely a memory 632 and a memory 634, which may be portions of main memory locally attached to the respective processors.

Processors 670, 680 may each exchange information with a network interface (NW I/F) 690 via individual interfaces 652, 654 using interface circuits 676, 694, 686, 698. The network interface 690 (e.g., one or more of an interconnect, bus, and/or fabric, and in some examples is a chipset) may optionally exchange information with a coprocessor 638 via an interface circuit 692. In some examples, the coprocessor 638 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 670, 680 or outside of both processors, yet connected with the processors via an interface such as P-P interconnect, such that either or both processors'local cache information may be stored in the shared cache if a processor is placed into a low power mode.

Network interface 690 may be coupled to a first interface 616 via interface circuit 696. In some examples, first interface 616 may be an interface such as a Peripheral Component Interconnect (PCI) interconnect, a PCI Express interconnect, or another I/O interconnect. In some examples, first interface 616 is coupled to a power control unit (PCU) 617, which may include circuitry, software, and/or firmware to perform power management operations with regard to the processors 670, 680 and/or co-processor 638. PCU 617 provides control information to one or more voltage regulators (not shown) to cause the voltage regulator(s) to generate the appropriate regulated voltage(s). PCU 617 also provides control information to control the operating voltage generated. In various examples, PCU 617 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 617 is illustrated as being present as logic separate from the processor 670 and/or processor 680. In other cases, PCU 617 may execute on a given one or more of cores (not shown) of processor 670 or 680. In some cases, PCU 617 may be implemented as a microcontroller (dedicated or general-purpose) or other control logic configured to execute its own dedicated power management code, sometimes referred to as P-code. In yet other examples, power management operations to be performed by PCU 617 may be implemented externally to a processor, such as by way of a separate power management integrated circuit (PMIC) or another component external to the processor. In yet other examples, power management operations to be performed by PCU 617 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 614 may be coupled to first interface 616, along with a bus bridge 618 which couples first interface 616 to a second interface 620. In some examples, one or more additional processor(s) 615, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 616. In some examples, second interface 620 may be a low pin count (LPC) interface. Various devices may be coupled to second interface 620 including, for example, a keyboard and/or mouse 622, communication devices 627 and storage circuitry 628. Storage circuitry 628 may be one or more non-transitory machine-readable storage media as described below, such as a disk drive or other mass storage device which may include instructions/code and data 630 and may implement the storage in some examples. Further, an audio I/O 624 may be coupled to second interface 620. Note that other architectures than the point-to-point architecture described above are possible. For example, instead of the point-to-point architecture, a system such as multiprocessor system 600 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

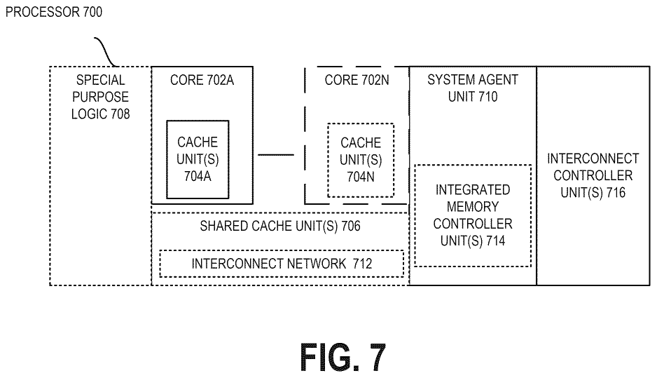

FIG. 7 illustrates a block diagram of an example processor and/or SoC in accordance with some embodiments. Processor and/or SoC 700 may have one or more cores and an integrated memory controller. The solid lined boxes illustrate a processor and/or SoC 700 with a single core 702(A), system agent unit circuitry 710, and a set of one or more interface controller unit(s) circuitry 716, while the optional addition of the dashed lined boxes illustrates an alternative processor and/or SoC 700 with multiple cores 702(A)-(N), a set of one or more integrated memory controller unit(s) circuitry 714 in the system agent unit circuitry 710, and special purpose logic 708, as well as a set of one or more interface controller unit(s) circuitry 716. Note that the processor and/or SoC 700 may be one of the processors 670 or 680, or co-processor 638 or 615 of FIG. 6.

Thus, different implementations of the processor and/or SoC 700 may include: 1) a CPU with the special purpose logic 708 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 702(A)-(N) being one or more general purpose cores (e.g., general purpose in-order cores, general purpose out-of-order cores, or a combination of the two); 2) a co-processor with the cores 702(A)-(N) being a large number of special purpose cores intended primarily for graphics and/or scientific (throughput); and 3) a co-processor with the cores 702(A)-(N) being a large number of general purpose in-order cores. Thus, the processor and/or SoC 700 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 700 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 704(A)-(N) within the cores 702(A)-(N), a set of one or more shared cache unit(s) circuitry 706, and external memory (not shown) coupled to the set of integrated memory controller unit(s) circuitry 714. The set of one or more shared cache unit(s) circuitry 706 may include one or more mid-level caches, such as level 2 (L2 ), level 3 (L3 ), level 4 (L4 ), or other levels of cache, such as a last level cache (LLC), and/or combinations thereof. While in some examples interface network circuitry 712 (e.g., a ring interconnect) interfaces the special purpose logic 708 (e.g., integrated graphics logic), the set of shared cache unit(s) circuitry 706, and the system agent unit circuitry 710, alternative examples use any number of well-known techniques for interfacing such units. In some examples, coherency is maintained between one or more of the shared cache unit(s) circuitry 706 and cores 702(A)-(N). In some examples, interface controller unit(s) circuitry 716 couple the cores 702(A)-(N) to one or more other devices 718 such as one or more I/O devices, storage, one or more communication devices (e.g., wireless networking, wired networking, etc.), etc.

In some examples, one or more of the cores 702(A)-(N) are capable of multi-threading. The system agent unit circuitry 710 includes those components coordinating and operating cores 702(A)-(N). The system agent unit circuitry 710 may include, for example, power control unit (PCU) circuitry and/or display unit circuitry (not shown). The PCU may be or may include logic and components needed for regulating the power state of the cores 702(A)-(N) and/or the special purpose logic 708 (e.g., integrated graphics logic). The display unit circuitry is for driving one or more externally connected displays.

The cores 702(A)-(N) may be homogenous in terms of instruction set architecture (ISA). Alternatively, the cores 702(A)-(N) may be heterogeneous in terms of ISA; that is, a subset of the cores 702(A)-(N) may be capable of executing an ISA, while other cores may be capable of executing only a subset of that ISA or another ISA.

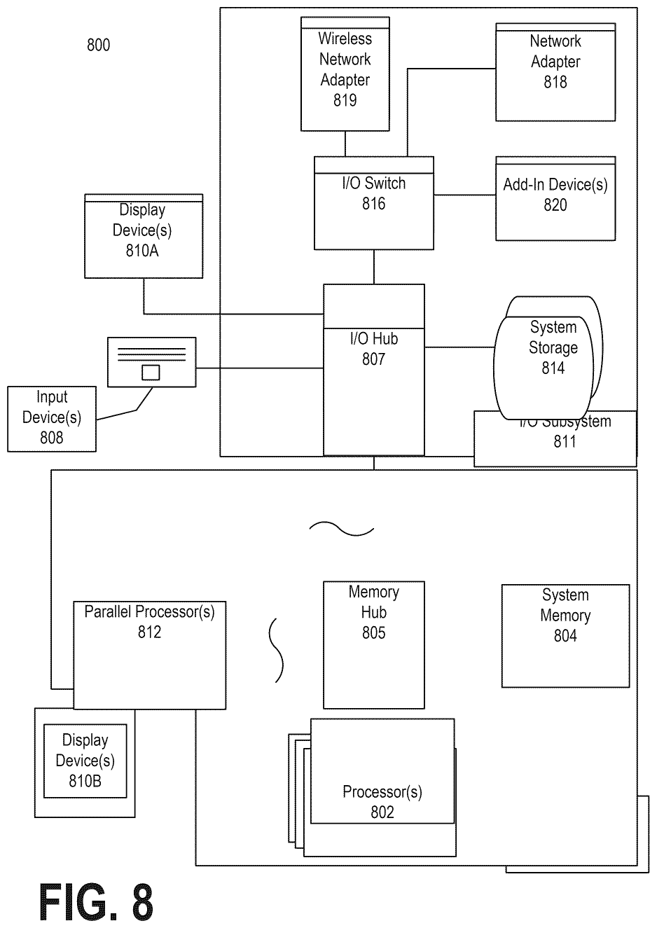

FIG. 8 is a block diagram illustrating a computing system 800 configured to implement one or more aspects of the examples described herein. The computing system 800 includes a processing subsystem 801 having one or more processor(s) 802 and a system memory 804 communicating via an interconnection path that may include a memory hub 805. The memory hub 805 may be a separate component within a chipset component or may be integrated within the one or more processor(s) 802. The memory hub 805 couples with an I/O subsystem 811 via a communication link 806. The I/O subsystem 811 includes an I/O hub 807 that can enable the computing system 800 to receive input from one or more input device(s) 808. Additionally, the I/O hub 807 can enable a display controller, which may be included in the one or more processor(s) 802, to provide outputs to one or more display device(s) 810A. In some examples the one or more display device(s) 810A coupled with the I/O hub 807 can include a local, internal, or embedded display device.

The processing subsystem 801, for example, includes one or more parallel processor(s) 812 coupled to memory hub 805 via a bus or communication link 813. The communication link 813 may be one of any number of standards-based communication link technologies or protocols, such as, but not limited to PCI Express, or may be a vendor specific communications interface or communications fabric. The one or more parallel processor(s) 812 may form a computationally focused parallel or vector processing system that can include a large number of processing cores and/or processing clusters, such as a many integrated core (MIC) processor. For example, the one or more parallel processor(s) 812 form a graphics processing subsystem that can output pixels to one of the one or more display device(s) 810A coupled via the I/O hub 807. The one or more parallel processor(s) 812 can also include a display controller and display interface (not shown) to enable a direct connection to one or more display device(s) 810B.

Within the I/O subsystem 811, a system storage unit 814 can connect to the I/O hub 807 to provide a storage mechanism for the computing system 800. An I/O switch 816 can be used to provide an interface mechanism to enable connections between the I/O hub 807 and other components, such as a network adapter 818 and/or wireless network adapter 819 that may be integrated into the platform, and various other devices that can be added via one or more add-in device(s) 820. The add-in device(s) 820 may also include, for example, one or more external graphics processor devices, graphics cards, and/or compute accelerators. The network adapter 818 can be an Ethernet adapter or another wired network adapter. The wireless network adapter 819 can include one or more of a Wi-Fi, Bluetooth, near field communication (NFC), or other network device that includes one or more wireless radios.

The computing system 800 can include other components not explicitly shown, including USB or other port connections, optical storage drives, video capture devices, and the like, which may also be connected to the I/O hub 807. Communication paths interconnecting the various components in FIG. 8 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 812 may incorporate circuitry optimized for graphics and video processing, including, for example, video output circuitry, and constitutes a graphics processing unit (GPU). Alternatively or additionally, the one or more parallel processor(s) 812 can incorporate circuitry optimized for general purpose processing, while preserving the underlying computational architecture, described in greater detail herein. Components of the computing system 800 may be integrated with one or more other system elements on a single integrated circuit. For example, the one or more parallel processor(s) 812, memory hub 805, processor(s) 802, and I/O hub 807 can be integrated into a system on chip (SoC) integrated circuit. Alternatively, the components of the computing system 800 can be integrated into a single package to form a system in package (SIP) configuration. In some examples at least a portion of the components of the computing system 800 can be integrated into a multi-chip module (MCM), which can be interconnected with other multi-chip modules into a modular computing system.

It will be appreciated that the computing system 800 shown herein is illustrative and that variations and modifications are possible. The connection topology, including the number and arrangement of bridges, the number of processor(s) 802, and the number of parallel processor(s) 812, may be modified as desired. For instance, system memory 804 can be connected to the processor(s) 802 directly rather than through a bridge, while other devices communicate with system memory 804 via the memory hub 805 and the processor(s) 802. In other alternative topologies, the parallel processor(s) 812 are connected to the I/O hub 807 or directly to one of the one or more processor(s) 802, rather than to the memory hub 805. In other examples, the I/O hub 807 and memory hub 805 may be integrated into a single chip. It is also possible that two or more sets of processor(s) 802 are attached via multiple sockets, which can couple with two or more instances of the parallel processor(s) 812.

Some of the particular components shown herein are optional and may not be included in all implementations of the computing system 800. For example, any number of add-in cards or peripherals may be supported, or some components may be eliminated. Furthermore, some architectures may use different terminology for components similar to those illustrated in FIG. 8. For example, the memory hub 805 may be referred to as a Northbridge in some architectures, while the I/O hub 807 may be referred to as a Southbridge.

### Example Embodiments

Illustrative examples of the technologies disclosed herein are provided below. An embodiment of the technologies may include any one or more, and any compatible combination of, the examples described below.

Example 1 is an apparatus that includes a transmitter driver circuit and an equalization circuit. The transmitter (Tx) driver circuit has a driver output node. Then equalization circuit is coupled between the driver output node and a channel input pad. The equalization circuit includes an RC filter coupled between the driver output node and an RC filter output node. The RC filter includes a first resistor coupled in parallel with a first capacitor. The equalization circuit also includes a first inductor coupled in series with a second resistor, and the first inductor and second resistor are coupled together between the RC filter output node and a low supply reference node.

Example 2 includes the subject matter of example 1, and wherein an output resistance of the Tx driver and equalization circuit together is substantially constant over a frequency range from 0 to at least 32 GHz.

Example 3 includes the subject matter of any of examples 1-2, and wherein the output resistance is from the channel input pad to the low supply reference through the Tx driver and equalization circuit.

Example 4 includes the subject matter of any of examples 1-3, and wherein substantially constant includes the output resistance remaining within 5% of a nominal value over the frequency range.

Example 5 includes the subject matter of any of examples 1-4, and wherein R1 and R2 substantially relate to each other in conformance with: R2=Rd+Rd2/R1.

Example 6 includes the subject matter of any of examples 1-5, and comprising a second inductor coupled in series between the RC filter output node and the channel input pad.

Example 7 includes the subject matter of any of examples 1-6, and wherein the Tx driver and equalization circuit are part of a UCIe (Universal Chiplet Interconnect Express) interconnect interface circuit.

Example 8 includes the subject matter of any of examples 1-7, and wherein the Tx driver and equalization circuit are part of a PCIe (Peripheral Component Interconnect Express) interconnect interface circuit.

Example 9 includes the subject matter of any of examples 1-8, and wherein the first and second inductors are disposed in over-lapping regions of separate metal layers of an integrated circuit device.

Example 10 includes the subject matter of any of examples 1-9, and wherein the Tx driver includes a voltage or a current mode driver.

Example 11 includes the subject matter of any of examples 1-10, and wherein the Tx driver is a voltage mode driver formed from either a P/N or an N/N driver circuit.

Example 12 is an apparatus that includes first and second chips. The first chip includes a first link interface circuit. The second chip includes a second link interface circuit coupled to the first link interface circuit. The first link interface circuit includes a plurality of transmitters that each include a transmitter (Tx) driver circuit and an equalization circuit. The Tx driver circuit includes a driver output node. The equalization circuit is coupled between the driver output node and a channel input pad. The equalization circuit includes an RC filter coupled between the driver output node and an RC filter output node. The RC filter includes a first resistor and a first capacitor. The equalization circuit also includes a first inductor coupled in series with a second resistor, wherein the first inductor and second resistor are coupled together between the RC filter output node and a low supply reference node.

Example 13 includes the subject matter of example 12, and wherein an output resistance of the Tx driver and equalization circuit together is substantially constant over a frequency range from 0 to at least 32 GHz.

Example 14 includes the subject matter of any of examples 12-13, and wherein the output resistance is from the channel input pad to the low supply reference through the Tx driver and equalization circuit.

Example 15 includes the subject matter of any of examples 12-14, and wherein substantially constant includes the output resistance remaining within 5% of a nominal value over the frequency range.

Example 16 includes the subject matter of any of examples 12-15, and wherein R1 and R2 substantially relate to each other in conformance with: R2=Rd+Rd×Rd/R1.

Example 17 includes the subject matter of any of examples 12-16, and comprising a second inductor coupled in series between the RC filter output node and the channel input pad.

Example 18 includes the subject matter of any of examples 12-17, and wherein the first and second inductors for each transmitter are disposed in over-lapping regions of separate metal layers of the first chip.

Example 19 includes the subject matter of any of examples 12-18, and wherein the Tx driver for each transmitter includes a voltage or a current mode driver.

Example 20 includes the subject matter of any of examples 12-19, and wherein the Tx driver is a voltage mode driver formed from either a P/N or an N/N driver circuit.

Example 21 is a method of manufacturing a transmitter circuit. The method includes coupling a transmitter (Tx) driver circuit to an equalization circuit at a driver output node. It also includes coupling an output of the equalization circuit to a channel input pad, the equalization circuit including (i) an RC filter coupled between the driver output node and an RC filter output node, the RC filter including a first resistor coupled in parallel with a first capacitor, and (ii) a first inductor coupled in series with a second resistor. The first inductor and second resistor being coupled together between the RC filter output node and a low supply reference node.

Example 22 includes the subject matter of example 21, and wherein an output resistance of the Tx driver and equalization circuit together is substantially constant over a frequency range from 0 to at least 32 GHz.

Example 23 includes the subject matter of any of examples 21-22, and wherein the output resistance is from the channel input pad to the low supply reference through the Tx driver and equalization circuit.

Example 24 includes the subject matter of any of examples 21-23, and wherein substantially constant includes the output resistance remaining within 5% of a nominal value over the frequency range.

Example 25 includes the subject matter of any of examples 21-24, and comprising using selected values of R1 and R2 such that R2 is substantially equal to Rd+Rd×Rd/R1.

Example 26 includes the subject matter of any of examples 21-25, and comprising installing a second inductor coupled in series between the RC filter output node and the channel input pad.

Example 27 includes the subject matter of any of examples 21-26, and comprising disposing the first and second inductors in over-lapping regions of adjacent metal layers of an integrated circuit device.

Example 28 includes the subject matter of any of examples 21-27, and wherein the Tx driver includes a voltage or a current mode driver.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

### Alternative Embodiments

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a transmitter (Tx) driver circuit with a driver output node; and
an equalization circuit coupled between the driver output node and a channel input pad, the equalization circuit including:
an RC (resistor-capacitor) filter coupled between the driver output node and an RC filter output node, the RC filter including a first resistor coupled in parallel with a first capacitor, and
a first inductor coupled in series with a second resistor, wherein the first inductor and second resistor are coupled together between the RC filter output node and a low supply reference node.

2. The apparatus of claim 1, wherein an output resistance of the Tx driver and equalization circuit together is substantially constant over a frequency range from 0 to a utilized interconnect Nyquist frequency.

3. The apparatus of claim 2, wherein the output resistance is from the channel input pad to the low supply reference through the Tx driver and equalization circuit.

4. The apparatus of claim 2, wherein substantially constant includes the output resistance remaining within 5% of a nominal value over the frequency range.

5. The apparatus of claim 1, wherein the first resistor is R1 and the second resistor is R2 and wherein R1 and R2 substantially relate to each other in conformance with: R2=Rd+Rd×Rd/R1, where Rd is a Tx driver resistance.

6. The apparatus of claim 1, comprising a second inductor coupled in series between the RC filter output node and the channel input pad.

7. The apparatus of claim 6, wherein the Tx driver and equalization circuit are part of a UCIe (Universal Chiplet Interconnect Express) interconnect interface circuit.

8. The apparatus of claim 6, wherein the Tx driver and equalization circuit are part of a PCIe (Peripheral Component Interconnect Express), DDR (double data rate), or High Speed Ethernet interconnect interface circuit.

9. The apparatus of claim 6, wherein the first and second inductors are disposed in over-lapping regions of separate metal layers of an integrated circuit device.

10. The apparatus of claim 1, wherein the Tx driver includes a voltage or a current mode driver.

11. The apparatus of claim 10, wherein the Tx driver is a voltage mode driver formed from either a P/N (a P-type transistor coupled to an N-type transistor) or an N/N driver circuit (an N-type transistor coupled to an N-type transistor).

12. An apparatus, comprising:
a first chip including a first link interface circuit, and
a second chip including a second link interface circuit coupled to the first link interface circuit, the first link interface circuit including a plurality of transmitters that each include:
a transmitter (Tx) driver circuit with a driver output node; and
an equalization circuit coupled between the driver output node and a channel input pad, the equalization circuit including:
an RC (resistor-capacitor) filter coupled between the driver output node and an RC filter output node, the RC filter including a first resistor and a first capacitor, and
a first inductor coupled in series with a second resistor, wherein the first inductor and the second resistor are coupled together between the RC filter output node and a low supply reference node.

13. The apparatus of claim 12, wherein an output resistance of the Tx driver and equalization circuit together is substantially constant over a frequency range from 0 to at least 32 GHz.

14. The apparatus of claim 12, wherein the first resistor is R1, the second resistor is R2, and R1 and R2 substantially relate to each other in conformance with: R2=Rd+Rd×Rd/R1, where Rd is a Tx driver resistance.

15. The apparatus of claim 12, comprising a second inductor coupled in series between the RC filter output node and the channel input pad.

16. The apparatus of claim 15, wherein the first and second inductors for each transmitter are disposed in over-lapping regions of separate metal layers of the first chip.

17. A method of manufacturing a transmitter circuit, comprising:
coupling a transmitter (Tx) driver circuit to an equalization circuit at a driver output node;
coupling an output of the equalization circuit to a channel input pad, the equalization circuit including:
an RC (resistor-capacitor) filter coupled between the driver output node and an RC filter output node, the RC filter including a first resistor coupled in parallel with a first capacitor, and
a first inductor coupled in series with a second resistor, wherein the first inductor and second resistor are coupled together between the RC filter output node and a low supply reference node.

18. The method of claim 17, wherein the first resistor is R1, the second resistor is R2, and the method further comprising using selected values of R1 and R2 such that R2 is substantially equal to Rd+Rd×Rd/R1, where Rd is a Tx driver resistance.

19. The method of claim 17, comprising installing a second inductor coupled in series between the RC filter output node and the channel input pad.

20. The method of claim 19, comprising disposing the first and second inductors in over-lapping regions of adjacent metal layers of an integrated circuit device.
